(19) United States
(12) Patent Application Publication
(10) Pub. No.: US 2007/0013408 A1
(43) Pub. Date: Jan. 18, 2007

(54) Inspection device for display panel and interface used therein

(75) Inventor: Naotoshi Hamamoto, Kokubunji-shi (JP)

Correspondence Address: Paul D. Greeley;Ohlandt, Greeley, Ruggiero & Perle, L.L.P., 10th Floor, One Landmark Square, Stamford, CT, 06901-2682, US

(73) Assignee: Agilent Technologies, Inc.

(21) Appl. No.: 11/455,449

(22) Filed: Jun. 19, 2006

(30) Foreign Application Priority Data
Jul. 13, 2005 (JP) P2005-204549

(51) Int. Cl. G01R 31/00

(52) U.S. Cl. 324/770

(57) ABSTRACT

An interface 100, which connects a prober 14 having a contact probe 15 which contacts an electrode pad on a display panel 12 with a test head 13 which applies a test signal to the electrode pad and detects an output signal from the electrode pad. The interface 100 includes a performance board 1 which is attached to the test head 13 and transmits the test signal, a connection board 2 which is attached to the prober 14 and wires a conductive pattern on the performance board 1 to a conductive pattern corresponding to the electrode pad on the display panel 12, an elastomer connecting body 3 which electrically connects a first connection pad group 5 formed on the performance board 1 with a second connection pad group 6 formed on the connection board 2, and a quick lock 4 which fixes the performance board 1 and connection board 2 releasably.

### TECHNICAL FIELD OF THE INVENTION

This invention relates to an inspection device for a display panel, in particular a flat panel display (abbreviated to FPD hereafter), and an interface used therein.

### BACKGROUND OF THE INVENTION

An FPD is structured such that a large number of closely-packed electrode pads are provided to correspond to a large number of pixels. Accordingly, an FPD comprises a larger number of measurement terminals than an IC or the like.

In an array inspection performed on a display panel, a contact probe of a prober is brought into contact with an electrode pad, a test signal is applied from a test head, and an output signal from the electrode pad is detected (Japanese Unexamined Patent Application Publication H4-184264). The test head and prober are generally connected using a connector and a cable as an interface.

### SUMMARY OF THE INVENTION

Hence, during an array inspection of an FPD having a large number of measurement terminals, many connectors and cables are required to connect the test heads and probers. Moreover, the electrode pad arrangement on an FPD differs in each FPD, and therefore the connectors and cables must be replaced with specialized connectors and cables whenever the type of FPD to be measured changes.

Thus when the type of FPD changes during an FPD array inspection, a great deal of time is expended in replacing the connectors with connectors suited to the FPD type and modifying the wiring to the cables attached to the connectors. This leads to a reduction in FPD production efficiency.

This invention has been designed in consideration of these problems, and it is an object thereof to provide an interface between a test head and a prober which can be exchanged easily when the display panel type changes during a display panel inspection, and an inspection device employing this interface.

In order to achieve above object, this invention provides an interface which connects a prober having a contact probe which contacts an electrode pad on a display panel with a test head which applies a test signal to the electrode pad and detects an output signal from the electrode pad. The interface comprises a first substrate which is attached to the test head and transmits the test signal, a second substrate which is attached to the prober and wires a conductive pattern on the first substrate to a conductive pattern corresponding to the electrode pad on the display panel, a plate which is sandwiched between the first substrate and the second substrate and electrically connects a first connection pad group formed on the first substrate with a second connection pad group formed on the second substrate, and a fixing mechanism which fixes the first substrate and second substrate releasably.

These and other objects, features, aspects and advantages of this invention will become apparent to those skilled in the art from the following detailed description, which, taken in conjunction with the annexed drawings, discloses preferred embodiments of this invention.

### BRIEF DESCRIPTION OF THE DRAWINGS

FIG. 1 is a pattern diagram showing a state of inspecting a display panel.

FIG. 2 is a perspective view of an interface 100 and an inspection device 101 employing the interface 100 according to an embodiment of this invention.

FIG. 3 is a plan view of the interface 100 and the inspection device 101 employing the interface 100.

FIG. 4 is a side view of the interface 100 and the inspection device 101 employing the interface 100.

FIG. 5A is a plan view of a performance board 1.

FIG. 5B is a side view of the performance board 1.

FIG. 6 is a plan view of a connection board 2.

FIG. 7A is a plan view of an elastomer connecting body 3.

FIG. 7B is a side view of the elastomer connecting body 3.

FIG. 8A is a plan view of a quick lock 4.

FIG. 8B is a section view along the b-b cross section in FIG. 8A.

FIG. 9A is a sectional view of the interface 100 prior to fixing by the quick lock 4.

FIG. 9B is a sectional view of the interface 100 following fixing by the quick lock 4.

FIG. 10 is a perspective view showing another aspect of the interface 100 and the inspection device 101 employing the interface 100 according to an embodiment of this invention.

FIG. 11A is a plan view showing another aspect of the performance board 1.

FIG. 11B is a plan view showing another aspect of the connection board 2.

### PREFERRED EMBODIMENTS OF THE INVENTION

An interface 100 and an inspection device 101 according to an embodiment of this invention will now be described with reference to the drawings.

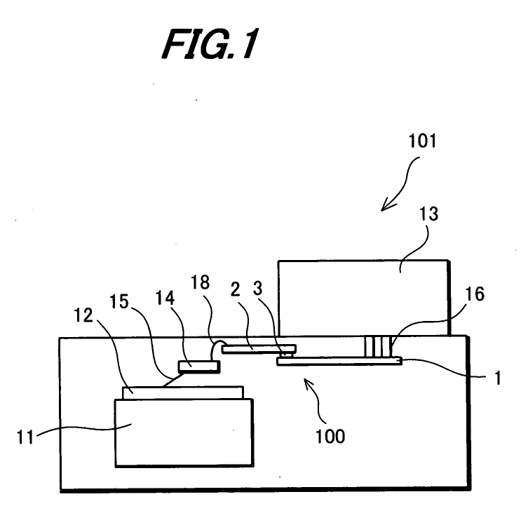

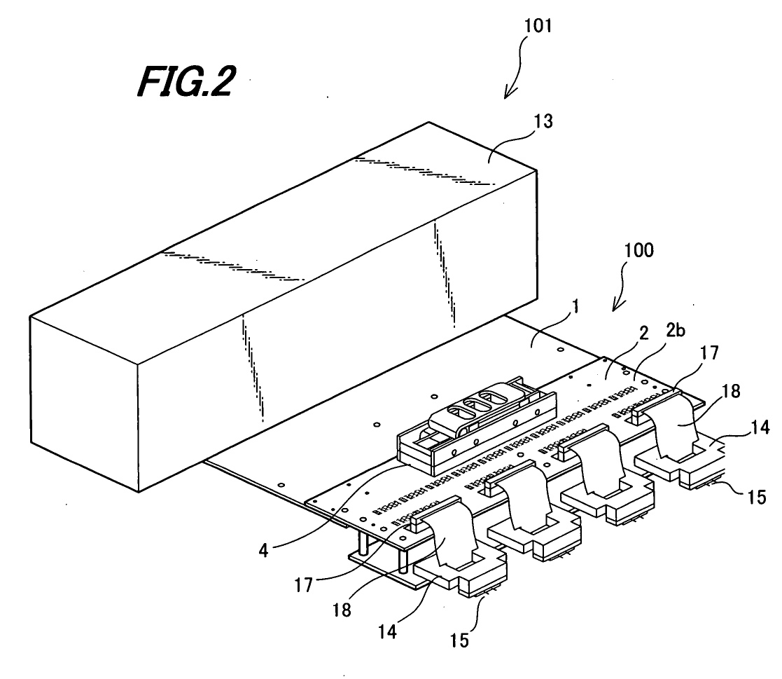

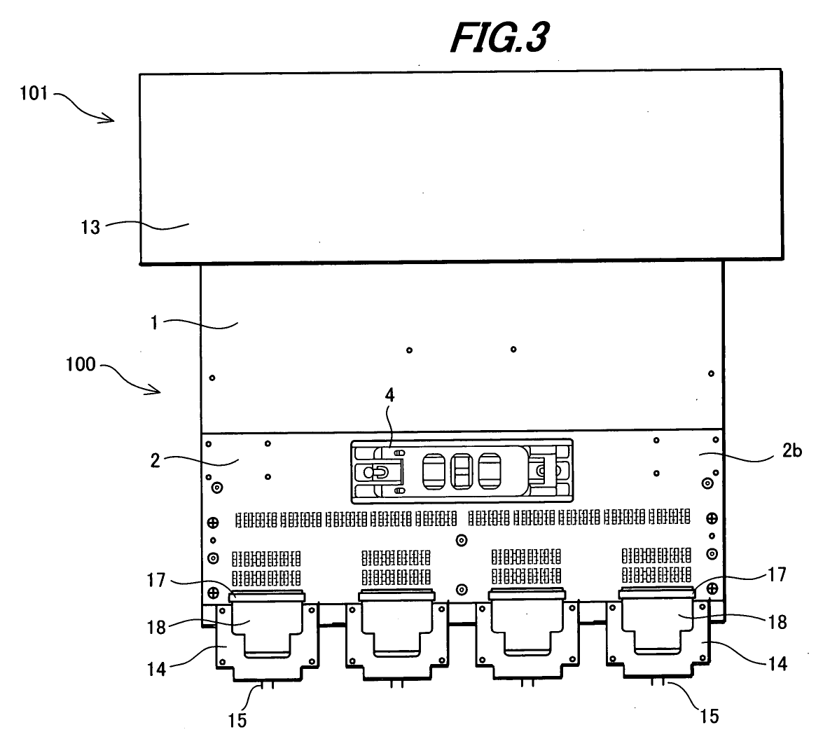

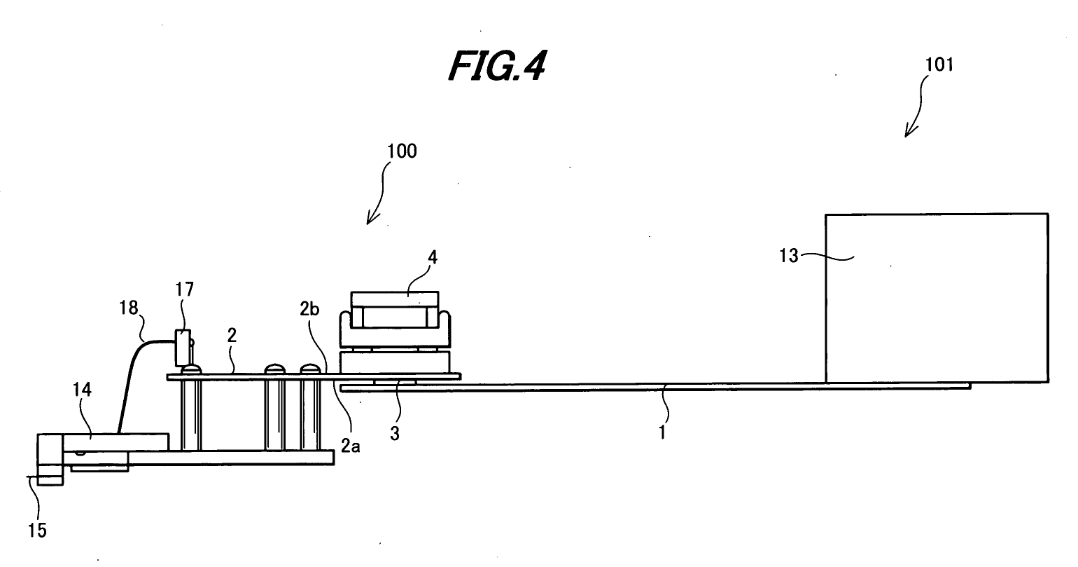

First, referring to FIGS. 1 through 4, the overall constitution of the interface 100 and inspection device 101 will be described.

The inspection device 101 is used to inspect the electric characteristics of an FPD 12 serving as a display panel which is a measurement object supported on a chuck 11. The inspection device 101 comprises a test head 13 which outputs an electric signal to electrode pads on the FPD 12, processes an electric signal from the electrode pads, and measures the electric characteristics of the FPD 12, and a prober 14 having a contact probe 15 which contacts the electrode pads on the FPD 12. The test head 13 and prober 14 are connected by the interface 100.

The FPD of this invention is a thin display panel such as a liquid crystal panel or an EL (electroluminescence) panel, for example an organic EL panel.

The interface 100 comprises a performance board 1 which is attached to the test head 13 and serves as a first substrate for transmitting a test signal from the test head 13, and a connection board 2 which is attached to the prober 14 by a connector 17 and a cable 18 and serves as a second substrate for wiring a conductive pattern on the performance board 1 to a conductive pattern corresponding to the electrode pads on the FPD 12.

The performance board 1 and connection board 2 are electrically connected via an elastomer connecting body 3 serving as a plate which is constituted by a plate sandwiched between the performance board 1 and connection board 2.

The elastomer connecting body 3 electrically connects a first connection pad group 5 formed on the performance board 1 with a second connection pad group 6 formed on the connection board 2.

The interface 100 further comprises a quick lock 4 serving as a fixing mechanism for fixing the performance board 1 and connection board 2 releasably.

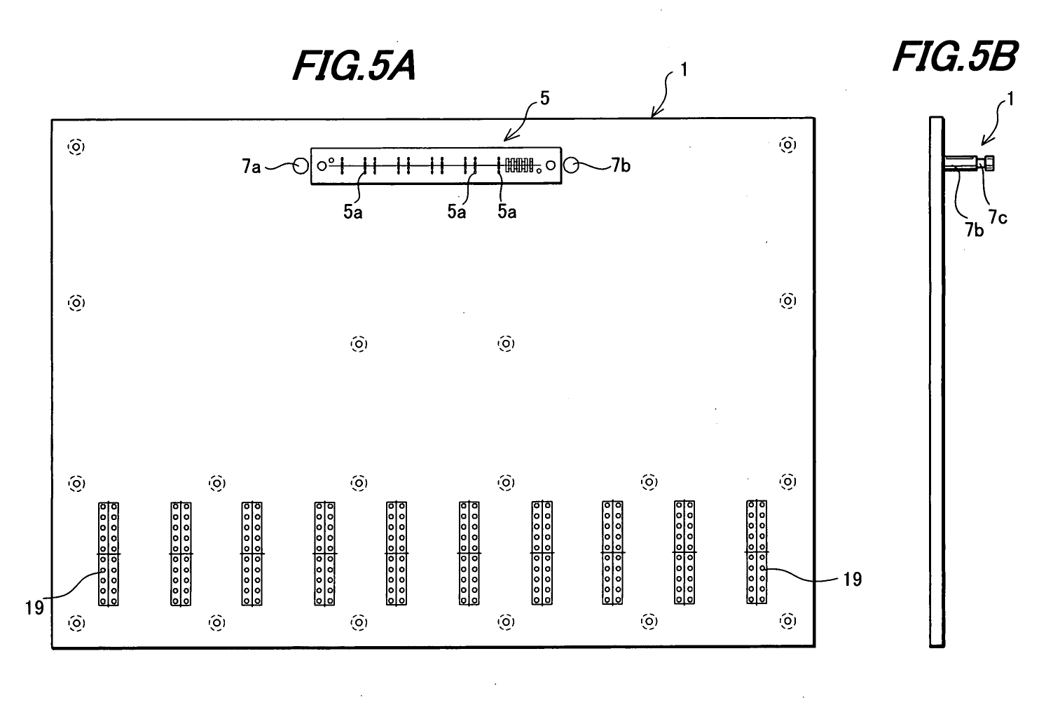

Next, referring to FIGS. 5 through 8, each member of the interface 100 will be described.

The performance board 1 is a substrate that can be used regardless of the display panel type to transmit a test signal from the test head 13 to the connection board 2. As shown in FIG. 5A, a pattern 19 is formed at the end portion of the performance board 1, and the test head 13 is electrically connected to this pattern 19 via a pogo pin 16.

The performance board 1 is also formed with a predetermined conductive pattern (not shown) for transmitting the test signal input from the test head 13 via the pattern 19, and the first connection pad group 5, which is constituted by a plurality of pads 5a connected electrically to the conductive pattern.

As shown in FIG. 5B, struts 7a, 7b are provided on either side of the first connection pad group 5 for connecting the performance board 1 with the connection board 2. The struts 7a, 7b are formed with a recessed portion 7c for engaging gripping portions 86a, 86b of the quick lock 4, to be described below.

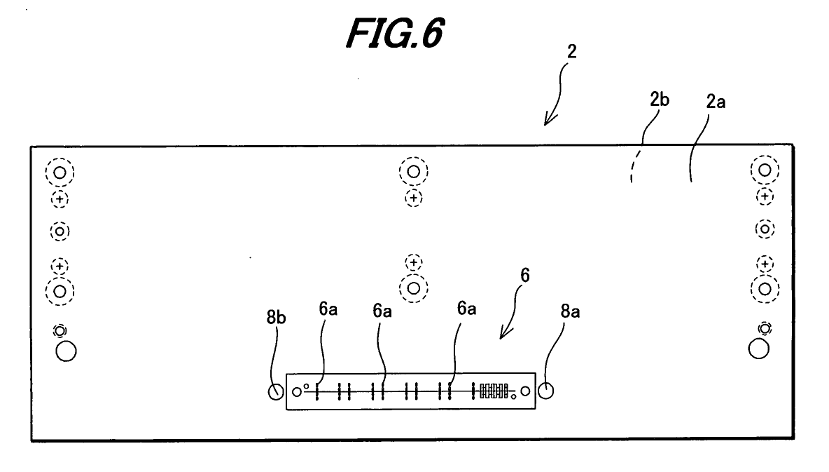

As shown in FIG. 6, the connection board 2 is formed with a conductive pattern (not shown) corresponding to the electrode pads on the FPD 12, and the second connection pad group 6, which is constituted by a plurality of pads 6a connected electrically to the conductive pattern.

A surface 2a shown in FIG. 6 opposes the performance board 1, and the second connection pad group 6 is formed on this surface 2a. The conductive pattern corresponding to the electrode pads on the FPD 12 is formed on a surface 2b of the connection board 2 which opposes the surface 2a. The conductive pattern and the second connection pad group 6 are connected by a through hole.

Opening portions 8a, 8b for inserting the struts 7a, 7b of the performance board 1 are formed on either side of the second connection pad group 6.

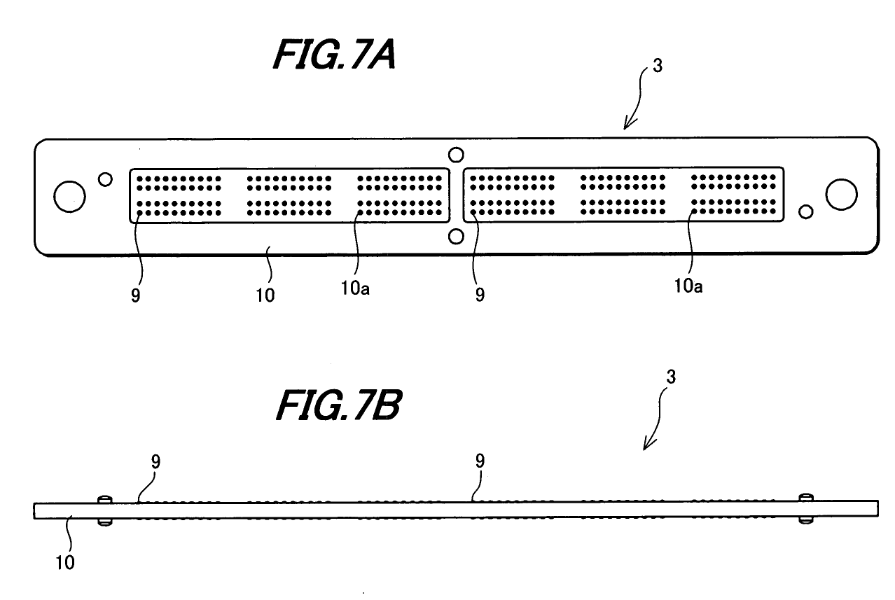

The elastomer connecting body 3 is a plate disposed between the performance board 1 and connection board 2 in a compressed state. As shown in FIGS. 7A, 7B, the elastomer connecting body 3 comprises a plurality of conductive rubbers 9 disposed in positions corresponding to the respective pads of the first connection pad group 5 and second connection pad group 6 so as to connect the two connection pad groups 5, 6 electrically, and an elastic plate 10 serving as an elastic supporting body which is an insulating body and supports the conductive rubbers 9. The performance board 1 and connection board 2 are electrically connected comprehensively by the elastomer connecting body 3.

A plurality of through holes 10a are provided in the elastic plate 10 at fixed intervals, and the conductive rubbers 9 are inserted into the through holes 10a in pin form. As shown in FIG. 7B, the conductive rubbers 9 have a larger dimension than the thickness of the elastic plate 10, and thus the first connection pad group 5 of the performance board 1 and the second connection pad group 6 of the connection board 2 can be connected securely. It should be noted that the conductive rubbers 9 are flexible, and therefore do not scratch the pads of the connection pad groups 5, 6.

Thus, the elastomer connecting body 3 is provided with a conducting property in the thickness direction by the conductive rubbers 9, and since the respective conductive rubbers 9 are insulated by the elastic plate 10 in the lengthwise direction, the elastomer connecting body 3 is also provided with an insulating property. In other words, the elastomer connecting body 3 is an anisotropic conductive body exhibiting electric anisotropy.

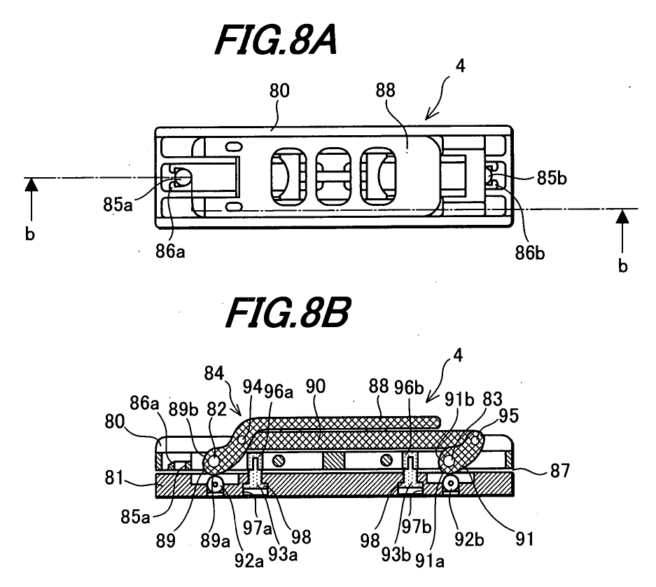

The quick lock 4 is used to fix the performance board 1 and connection board 2, which are electrically connected by the elastomer connecting body 3. As shown in FIGS. 8A, 8B, the quick lock 4 comprises an upper portion 80, a base portion 81, a linking mechanism 84 connected to the upper portion 80 via rotary fulcrums 82, 83, opening portions 85a, 85b for inserting the struts 7a, 7b of the performance board 1, and the gripping portions 86a, 86b, which are attached to the upper portion 80 for gripping the recessed portion 7c of the struts 7a, 7b.

The gripping portions 86a and 86b are urged in a direction away from each other (toward the outside in the lengthwise direction of the quick lock 4) by an urging member (not shown).

The upper portion 80 and base portion 81 are connected by screwing bolts 93a, 93b inserted into through holes 97a, 97b provided in the base portion 81 into female screw portions 96a, 96b provided in the upper portion 80.

The bolts 93a, 93b are slidable in relation to the through holes 97a, 97b. However, the bolts 93a, 93b are provided with a stopper 98 which engages with a stepped portion formed on the inner periphery of the through holes 97a, 97b. Thus the upper portion 80 and base portion 81 are connected so as to be capable of relative movement by a predetermined distance (a gap 87 shown in FIG. 8B).

The linking mechanism 84 is constituted by an operating lever 88, a cam portion 89 formed on the end portion of the operating lever 88, which rotates about the rotary fulcrum 82, a connecting rod 90 connected to the operating lever 88 via a rotary fulcrum 94, and a cam 91 connected to the connecting rod 90 via a rotary fulcrum 95, which rotates about the rotary fulcrum 83. The linking mechanism 84 operates when the operating lever 88 is rotated.

The cam portion 89 comprises a crest portion 89a and a base portion 89b, and is disposed in contact with a cam receiving portion 92a attached auto-rotatably to the base portion 81. The cam 91 also comprises a crest portion 91a and a base portion 91b, and is disposed in contact with a cam receiving portion 92b.

When the operating lever 88 of the quick lock 4 constituted as described above is rotated, the linking mechanism 84 operates such that the cam portion 89 and the cam 91 roll around the cam receiving portions 92a, 92b about the respective rotary fulcrums 82, 83. As the contact positions of the cam portion 89 and cam 91 with respect to the cam receiving portions 92a, 92b shift from the base portions 89b, 91b to the crest portions 89a, 91a, the cam receiving portions 92a, 92b are pressed by the cam portion 89 and cam 91. As a result, the base portion 81 to which the cam receiving portions 92a, 92b are attached moves in a direction away from the upper portion 80, to which the cam portion 89 and cam 91 are attached, by a distance corresponding to the gap 87. Thus, by the action of the cam portion 89 and the cam 91, the base portion 81 moves relative to the upper portion 80.

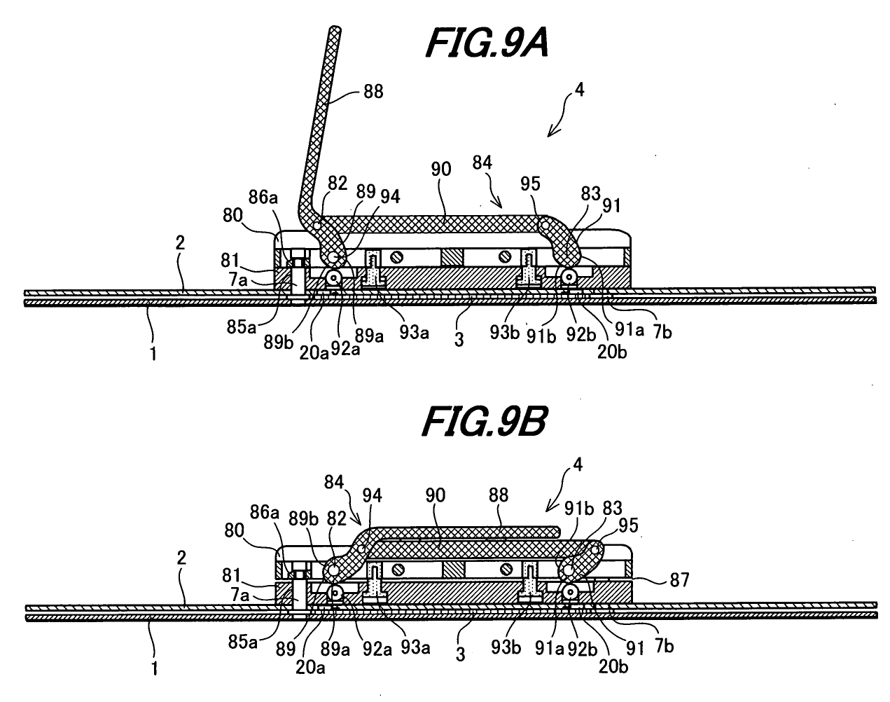

A method of electrically connecting the performance board 1 and connection board 2 and a method of mechanically fixing the performance board 1 and connection board 2 will now be described with reference to FIGS. 9A and 9B. FIG. 9A is a sectional view of the interface 100 prior to fixing by the quick lock 4, and FIG. 9B is a sectional view of the interface 100 following fixing. The sectional views in FIGS. 9A, 9B show the same cross-section as that of FIG. 8B.

First, the elastomer connecting body 3 is connected to the first connection pad group 5 of the performance board 1 using bolts 20a, 20b serving as fastening members. As a result, the first connection pad group 5 and elastomer connecting body 3 are electrically connected.

Next, the struts 7a, 7b provided on the performance board 1 are inserted into the opening portions 8a, 8b in the connection board 2. The second connection pad group 6 provided on the surface 2a of the connection board 2 contacts the elastomer connecting body 3. As a result, the first connection pad group 5 of the performance board 1 and the second connection pad group 6 of the connection board 2 are electrically connected via the elastomer connecting body 3.

However, in this state the performance board 1 and connection board 2 are not mechanically fixed. Therefore, the quick lock 4 is used to fix the two boards.

First, the quick lock 4 is set such that the operating lever 88 is removed from the upper portion 80, or in other words such that the base portions 89b, 91b of the cam portion 89 and cam 91 are in contact with the cam receiving portions 92a, 92b.

Next, the gripping portions 86a and 86b attached to the upper portion 80 are moved in a direction approaching each other (toward the inside in the lengthwise direction of the quick lock 4) against the urging force of the urging member. In this state, the quick lock 4 is disposed on the connection board 2 as shown in FIG. 9A such that the struts 7a, 7b provided on the performance board 1 are inserted into the opening portions 85a, 85b in the quick lock 4.

The gripping portions 86a and 86b are then returned to their original state so as to engage with the recessed portion 7c of the struts 7a, 7b through the urging force of the urging member. As a result, the upper portion 80 of the quick lock 4 is fixed to the struts 7a, 7b on the performance board 1.

Next, as shown in FIG. 9B, the operating lever 88 is rotated in a direction approaching the upper portion 80. In so doing, the linking mechanism 84 is operated such that the contact positions of the cam portion 89 and cam 91 with respect to the cam receiving portions 92a, 92b shift from the base portions 89b, 91b to the crest portions 89a, 91a. As a result of this shift, the cam receiving portions 92a, 92b are pressed by the cam portion 89 and cam 91.

At this time, the upper portion 80 is fixed to the performance board 1 via the gripping portions 86a, 86b and struts 7a, 7b, and therefore the base portion 81, to which the cam receiving portions 92a, 92b are attached, presses the connection board 2 toward the performance board 1 between the upper portion 80 and the performance board 1.

As a result of the pressing force exerted by the base portion 81, the elastic plate 10 of the elastomer connecting body 3, disposed between the performance board 1 and the connection board 2, is compressed. Accordingly, the base portion 81 moves by the gap 87 so as to urge the connection board 2 toward the performance board 1. In this manner the performance board 1 and connection board 2 are fixed.

Hence, the performance board 1 and connection board 2 are fixed by the urging force that is generated through rotation of the cam portion 89 and cam 91. Furthermore, since the elastomer connecting body 3 is disposed between the performance board 1 and connection board 2 in a compressed state, the performance board 1 and connection board 2 are electrically connected securely.

To release the performance board 1 and connection board 2, the operating lever 88 of the quick lock 4 is rotated in a direction away from the upper portion 80. As a result, the contact positions of the cam portion 89 and cam 91 with respect to the cam receiving portions 92a, 92b shift from the crest portions 89a, 91a to the base portion 89b, 91b such that the pressing force exerted on the base portion 81 is released.

As described above, the test head 13 and prober 14 are connected by the interface 100, which comprises the electrically connected and mechanically fixed performance board 1 and connection board 2, and together these components constitute the display panel inspection apparatus 101.

As shown in FIGS. 1 to 4, an electric signal output from the test head 13 is transmitted to the performance board 1, the first connection pad group 5, the elastomer connecting body 3, the second connection pad group 6, and the connection board 2. The electric signal is then transmitted to the prober 14 through the connector 17 and cable 18, and then transmitted to the electrode pads on the FPD 12 via the contact probe 15.

According to the interface 100 and inspection apparatus 101 of the embodiment described above, the prober 14 is connected to the performance board 1, which can be used regardless of the FPD 12 type, by the connection board 2 which is employed in accordance with the FPD 12 type, while the connection pad groups 5, 6 of the performance board 1 and connection board 2 are connected comprehensively via the elastomer connecting body 3. Hence, when the FPD 12 type changes during an array inspection of the FPD 12, only the connection board 2 need be replaced with a connection board 2 corresponding to the FPD 12 type.

Furthermore, the connection board 2 is electrically connected to the performance board 1 by the elastomer connecting body 3 alone, and the connection between the elastomer connecting body 3 and connection board 2 can be released simply by operating the operating lever 88 of the quick lock 4. Thus the connection board 2 can be replaced easily.

Since the connection board 2 is not connected to the performance board 1 using a connector and cable, operational efficiency is greatly improved when the FPD type changes during an inspection of a display panel such as the FPD 12, having a large number of closely-packed electrode pads and a large number of measurement terminals. Moreover, since cables are not used, the reliability of the inspection is also improved.

This invention is not limited to the embodiment described above, and may of course be subjected to various modifications within the scope of the technical spirit thereof.

For example, as long as the connection board 2 can be urged toward the performance board 1 side, the quick lock 4 need not be used to fix the performance board 1 and connection board 2 mechanically, and instead a bolt or the like may be employed.

Further, in the above embodiment, the connection board 2 is disposed above the performance board 1 and the quick lock 4 is disposed on the connection board 2, but a constitution in which the performance board 1 is disposed above the connection board 2 and the quick lock 4 is disposed on the performance board 1 may be adopted. In this case, the struts 7a, 7b are provided on the connection board 2 and the quick lock 4 urges the performance board 1 toward the connection board 2.

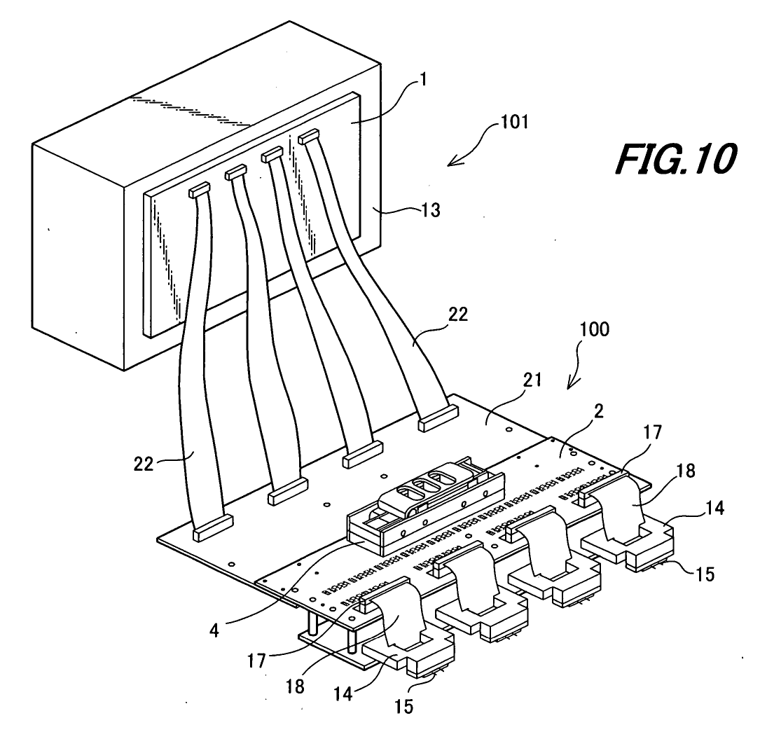

Further, as shown in FIG. 10, in cases where the test head 13 is disposed in a location removed from the prober 14, a relay substrate 21 which can be used regardless of the display panel type is provided when connecting the test head 13 with the performance board 1. Here, the performance board 1 is attached to the test head 13 by a pogo pin or the like, the performance board 1 and the relay substrate 21 are connected by a cable 22, and the relay substrate 21 is connected to the connection board 2 using the elastomer connecting body 3 and the quick lock 4. Thus the relay substrate 21 is attached to the test head 13 by the performance board 1 and cable 22. In this aspect, the relay substrate 21 corresponds to the first substrate, and when the FPD 12 type changes during an array inspection of the FPD 12, the connection board 2 is simply replaced by a connection board 2 corresponding to the FPD 12 type, as in the above embodiment.

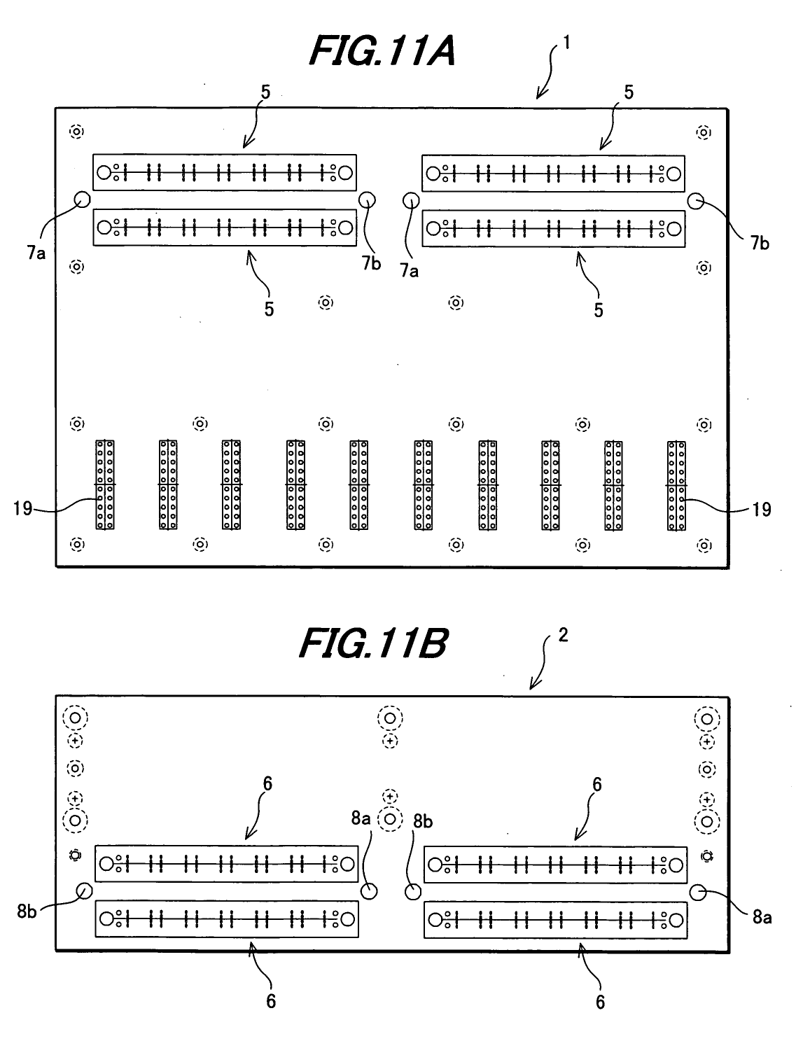

Furthermore, in the above embodiment the performance board 1 and connection board 2 are connected with the first connection pad group 5, elastomer connecting body 3, second connection pad group 6, and quick lock 4 serving as a single unit. However, as shown in FIGS. 11A, 11B, a plurality of connection pad groups may be formed on each of the performance board 1 and connection board 2 such that the performance board 1 and connection board 2 are connected using a plurality of units. It is also possible to fix a plurality of the elastomer connecting bodies 3 (two bodies in FIGS. 11A, 11B) using a single quick lock 4.

What is claimed is:

1. An interface which connects a prober having a contact probe which contacts an electrode pad on a display panel with a test head which applies a test signal to the electrode pad and detects an output signal from the electrode pad, the interface comprising:
a first substrate which is attached to the test head and transmits the test signal;
a second substrate which is attached to the prober and wires a conductive pattern on the first substrate to a conductive pattern corresponding to the electrode pad on the display panel;
a plate which is sandwiched between the first substrate and the second substrate and electrically connects a first connection pad group formed on the first substrate with a second connection pad group formed on the second substrate; and
a fixing mechanism which fixes the first substrate and second substrate releasably.

2. The interface according to claim 1, wherein the plate comprises:
a conductive rubber which electrically connects the first connection pad group with the second connection pad group; and
an elastic supporting body which supports the conductive rubber.

3. The interface according to claim 1, wherein the fixing mechanism is disposed in contact with either of the first substrate and the second substrate, and urges the contacted substrate toward the other substrate.

4. The interface according to claim 3, wherein an urging force in the fixing mechanism is generated by rotating a cam.

5. The interface according to claim 1, wherein the display panel is a flat panel display.

6. An inspection device for a display panel, wherein a prober and a test head are connected by the interface as defined in claim 1.
